(19) United States
(12) Patent Application Publication
(10) Pub. No.: US 2005/0283714 A1
(43) Pub. Date: Dec. 22, 2005

(54) Method and apparatus for multiplication in Galois field, apparatus for inversion in Galois field and apparatus for AES byte substitution operation

(75) Inventors: Tymur Korkishko, Suwon-si (KR); Elena Trichina, Munich (DE); Kyung-hee Lee, Yongin-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., LTD., Suwon-si (KR)

(21) Appl. No.: 11/155,569

(22) Filed: Jun. 20, 2005

(30) Foreign Application Priority Data
Jun. 19, 2004 (KR) 2004-0045818

(51) Int. Cl. H03M 13/00; G06F 11/00

(52) U.S. Cl. 714/781

(57) ABSTRACT

A method and apparatus for multiplication in a Galois field. The method of multiplication in a Galois field (GF) for preventing an information leakage attack by performing a transformation of masked data and masks in GF(2ⁿ) includes: receiving a plurality of first and second masked input data, a plurality of first and second input masks and an output mask; calculating a plurality of intermediate values by performing a multiplication of the plurality of masked input data and the plurality of input masks in GF(2ⁿ); and calculating a final masked output value by performing an XOR operation of the intermediate values and the output masks.

### CROSS-REFERENCE TO RELATED APPLICATION

This application claims benefit under 35 U.S.C. § 119 from Korean Patent Application No. 2004-45818, filed on Jun. 19, 2004, the content of which is incorporated herein by reference.

### BACKGROUND OF THE INVENTION

1. Field of the Invention

The present invention relates to the cipher security process in a microelectronic assembly such as a smart card, and more particularly, to the prevention of cipher security infringement when a Differential Power Analysis attack is used in implementing the Advanced Encryption Standard.

2. Description of Related Art

Differential power analysis (DPA) is very strong attack technology that uses information leaking through power consumption of an appliance that processes data with a secret key. However, an attacker can also use an additional leak channel that is called a “side channel” such as electromagnetic radiation, erroneous output, time, etc.

A secret key block cipher performs computation using a secret key for all peripheral functions. When an access is performed using a secret key, an attacker may use another side channel and obtain information about the secret key. Thereafter, the attacker can discover a correlation between leaked information and the actual value of the secret key using a digital process and statistical method.

Symmetric block ciphers are widely used in cipher blocks such as a smart card. The symmetric block cipher operates with a fixed number of input bits and these bits are encrypted/decrypted to a fixed number of output bits. The encryption/decryption function is established using a simple function called a “round function”. By iteratively applying the round function for a specified number of times, the security of encryption algorithm can be obtained. Such ciphers are also called “iterative block cipher”.

A rijndael algorithm is known as a general example of the iterative block cipher algorithm. Rijndael algorithm has been established as the Advanced Encryption Standard (AES) for encryption of documents and data information which are transmitted through a network or stored in a smart card and storage device of a computer. According to the AES algorithm, a rijndael algorithm performs the symmetric block encryption by processing data blocks of 128 bits using encryption keys of 128 bits, 192 bits and 256 bits, and outputs encrypted data of 128 bits. Although the data block may have a bit number other than 128 bits, The AES standard has adopted 128 bits.

FIG. 1 is a view illustrating structures of input data, state array having converted input data and encrypted or decrypted output data in a general AES rijndael algorithm.

Referring to FIG. 1, 128-bit blocks of input data 101, status data 102 and output data 103 have a matrix structure composed of four 32-bit columns. The input data 101 is encrypted or decrypted to create the output data 103. Data created by performing respective operations of an encryption or decryption process with respect to the input data is the status data 102.

Generally, the AES rijndael algorithm iteratively performs a series of processes each called a “round”. FIGS. 2A and 2B are flowchart illustrating one round in a general rijndael algorithm.

Referring to FIG. 2A, a process composed of a plurality of operations are performed with respect to input status data, and this process is called an AES round. One AES round of the input status data is performed through a rijndael byte substitution operation S201, a shift row operation S203, a mixed column S205 and a round key addition S207.

In the byte substitution operation S201, a non-linear byte substitution operation is independently performed with respect to respective bytes of the data using a substitution table called an “S-box”. This “S-box” is constructed by performing inversion operation of multiplication in the finite field GF(2⁸) and affine transformation in GF(2⁸).

In the shift row operation S203, respective byte values of three columns except the first column of the status data 102 are not changed, but only their positions are changed.

In the mixed column operation S205, respective rows of the status data 102 are treated as coefficients of respective terms of a polynomial having four terms in GF(2⁸), and then transformed into coefficients of four terms of a polynomial corresponding to remainders obtained by multiplying the polynomial by a preset polynomial “a(x)={03}x3+{01}x2+{01}x+{02}” and then dividing the polynomial by “x4+1”.

In the round key addition S207, a round key is added to the status data 102 by performing an XOR operation in the unit of a bit. The detailed operation process of the respective steps of a round in the AES rijndael algorithm is known in the art, and thus the detailed explanation thereof will be omitted.

Meanwhile, in FIG. 2B, another AES round is illustrated. Referring to FIG. 2B, the AES round includes a shift row operation S211, a byte substitution operation S213, a mixed column operation S215 and a round key addition S217.

The AES round of FIG. 2B is equal to the AES round of FIG. 2A except that the order of the shift row operation S211 and the byte substitution operation S213 is reversed. The same result can be obtained through the AES round of FIG. 2B in comparison to the AES round of FIG. 2A even if the shift row operation step S211 and the byte substitution operation S213 are performed in reverse order.

According to the AES algorithm, data is encrypted by iteratively performing the AES round for a specified number of times. The number of AES round iterations Nr is determined according to the length of the encryption key. With respect to the encryption keys of 128 bits, 192 bits and 256 bits, “Nr=10”, “Nr=12” and “Nr=14”, respectively.

In the last AES round, after the AES round is iteratively performed for a specified number of times, the shift row step and the byte substitution operation step are performed in order or in reverse order, and then the round key addition step is performed without performing the mixed column step to create the output data 103 as shown in FIG. 1.

Meanwhile, a decryption process according to an AES rijndael algorithm corresponds to a reverse process of the encryption process according to the AES rijndael algorithm as described above. Accordingly, the input data is decrypted through a rijndael inverse byte substitution operation step, an inverse shift row operation, an inverse mixed column operation step and a round key addition operation S207. A decryption process according another AES operation is similar to that of the AES operation as described above, and the detailed explanation thereof will be omitted.

Up to now, many apparatuses for implementing the AES rijndael algorithm have been proposed. One of them is an apparatus having a structure in that one data processing module iteratively performs all AES rounds. Accordingly, since “Nr” times operations are performed with respect to one data through the data processing module while “Nr” times rounds are performed, the time required to perform all the rounds becomes “Nr” times as much as one round.

There are many methods and apparatuses for preventing information leakage attack against AES. These methods and apparatuses include a certain register backup charging, interleaved process of actual and random data and data masking technology. The most important technology that can resist the information leakage attack is the data masking technology. This technology makes data masked by an unforeseeable mask using XOR operations and so on. In this case, necessary computations are included in the masked data. In order to obtain the final data, the result of the masked computation should be “unmasked”. For this, the mask that is used to mask the input data should be processed by a specified method. This mask processing method is called a “mask correction”.

If it is assumed that the AES encryption block is integrated into a resource-qualified environment such as a smart card, a function required for an encryption/decryption circuit is to keep a processing speed of a specified level with the scale of the circuit kept small. An AES round function includes linear and non-linear parts. The mask correction of the linear part is directly performed, but the masked data process and mask correction in the non-linear part, i.e., the byte substitution in the non-linear part, requires a special computation. A conventional technology for the masked computation of byte substitution refers to a masking multiplication, AND operation masking, table search, etc.

A main part that affects the circuit scale is a byte substitution operation part. If the byte substitution operation and an inverse byte substitution operation are performed in the same circuit, the circuit size becomes almost double. A general apparatus for the byte substitution and inverse byte substitution operations uses operations in GF(2⁸), and includes the byte substitution, inverse byte substitution and direct logic synthesis from a lookup table.

However, the circuit scale of the conventional byte substitution and inverse byte substitution operation apparatus is not suitable for the resource-qualified environment. It is known that a large-scaled circuit is required for the byte substitution and inverse byte substitution. An approaching method that creates special crossbars and multiplexers for the byte substitution operation of the masked data causes the scale of the circuit to become large.

In order to perform an inversion in the mask byte substitution of hardware, data transformation from the field GF(2⁸) to the opposite field GF((2⁴)²) is required and computation of the opposite field is performed. This technology makes it possible to reduce the number of gates for the byte substitution. One of the most important works in computing the byte substitution of the opposite field is an inversion of operand of the opposite field.

A general technology for performing the inversion requests various operations in GF(2ⁿ), for example, multiplication, square operation, constant multiplication, addition and inversion. One of the most important operations that consume resources is multiplication in GF(2ⁿ).

In order to implement the masked byte substitution, the masking operation is required with respect to all operations. If the above-described conventional method is used to perform multiplication, the scale of hardware required to perform the masked byte substitution becomes great.

### BRIEF SUMMARY

The present invention has been developed in order to solve the above drawbacks and other problems associated with the conventional arrangement. An aspect of the present invention provides a method and apparatus for multiplication in a Galois field (GF) that performs an efficient multiplication of masked data in GF(2ⁿ).

Another aspect of the present invention provides an apparatus for inversion in a Galois field that performs an inversion of masked data in GF((2⁴)²) using a masked multiplication in GF(2⁴).

Still another aspect of the present invention provides an apparatus for AES byte substitution operation that performs an AES byte substitution operation of masked data using a masked inversion in GF((2⁴)²).

According to another aspect of the present invention, there is provided a method for multiplication in a Galois field for preventing an information leakage attack by performing a transformation of masked data and masks in GF(2ⁿ), including: receiving a plurality of first and second masked input data, a plurality of first and second input masks and an output mask; calculating a plurality of intermediate values by performing a multiplication of the plurality of masked input data and the plurality of input masks in GF(2ⁿ); and calculating a final masked output value by performing an XOR operation of the intermediate values and the output masks.

The first input data may refer to a value obtained by performing an XOR operation of a first input operand and the first input mask, and the second input data may refer to a value obtained by performing an XOR operation of a second input operand and the second input mask.

The intermediate value calculation operation may include: calculating a first intermediate value by performing an XOR operation of the first input data and the second input data, calculating a second intermediate value by performing an XOR operation of the second input data and the first input mask, calculating a third intermediate value by performing an XOR operation of the first input data and the second input mask, and calculating a fourth intermediate value by performing an XOR operation of the first input mask and the second input mask.

The final output value may be calculated by a following equation
MP=OM⊕A4⊕A3⊕A2⊕A1,
wherein ^{U} denotes the XOR operation, OM the output mask, A1 the first intermediate value, A2 the second intermediate value, A3 the third intermediate value and A4 the fourth intermediate value.

According to another aspect of the present invention, there is provided an apparatus for multiplication in a Galois field for preventing an information leakage attack by performing a transformation of masked data and masks in GF(2ⁿ), including: a plurality of multipliers receiving from an outside a plurality of first and second masked input data, a plurality of first and second input masks and an output mask, and calculating intermediate values by performing a multiplication of the plurality of masked input data and the plurality of input masks in GF(2ⁿ); and an XOR operation unit calculating a final masked output value by performing an XOR operation of the intermediate values and the output masks.

The first input data may refer to a value obtained by performing an XOR operation of a first input operand and the first input mask, and the second input data may refer to a value obtained by performing an XOR operation of a second input operand and the second input mask.

The plurality of multipliers may include a first multiplier for calculating a first intermediate value by performing an XOR operation of the first input data and the second input data, a second multiplier for calculating a second intermediate value by performing an XOR operation of the second input data and the first input mask, a third multiplier for calculating a third intermediate value by performing an XOR operation of the first input data and the second input mask, and a fourth multiplier for calculating a fourth intermediate value by performing an XOR operation of the first input mask and the second input mask.

The final output value may be calculated by a following equation:
MP=OM⊕A4⊕A3⊕A2⊕A1,
wherein ⊕ denotes the XOR operation, OM the output mask, A1 the first intermediate value, A2 the second intermediate value, A3 the third intermediate value and A4 the fourth intermediate value.

According to still another aspect of the present invention, there is provided an apparatus for inversion in a Galois field for receiving first to fifth input data from an outside and performing and inversion of the input data in GF((2⁴)²), including: a first exclusive OR (XOR) operation unit calculating a first resultant value T1 by receiving and performing an XOR operation on an upper bit part and a lower bit part of the fifth input data composed of 8 bits; a second exclusive OR (XOR operation unit calculating a first correction value M1 for performing a mask correction of the first resultant value T1 by receiving and performing an XOR operation on an upper bit part and a lower bit part of the third input data composed of 8 bits; a first masked multiplier calculating a second operation value T2 by receiving and performing a multiplication on the first resultant value T1, the lower bit part of the fifth input data, the first correction value M1, the lower bit part of the third input data and the fourth input data in GF(2⁴); a first operation unit calculating a third operation value T3 by receiving and performing a specified operation on the upper bit part of the fifth input data; a second operation unit calculating a second correction value M2 for correcting the third operation value T3 by receiving and performing a specified operation on the upper bit part of the third input data; a third XOR operation unit calculating a fourth operation value T4 by receiving and performing an XOR operation on the third operation value T3 and the second operation value T2; a fourth XOR operation unit calculating a third correction value M3 for performing a mask correction on the fourth operation value T4 by receiving and performing an XOR operation on the second correction value M2 and the fourth input data; a masked inverter calculating a fifth operation value (T5) by receiving and performing an inversion operation on the fourth operation value T4, the third correction value M3 and a lower bit part of the first input data in GF(2⁴); a second masked multiplier calculating a lower bit part of a final output value by receiving and performing a multiplication on the fifth operation value, the first operation value, the second input data, the first correction value and the lower bit part of the first input data in GF(2⁴); and a third masked multiplier calculating an upper bit part of the final output value by receiving and performing a multiplication on the fifth operation value, the lower bit part of the fifth input data, the second input data, the upper bit part of the third input data and an upper bit part of the first input data in GF(2⁴).

According to still another aspect of the present invention, there is provided an apparatus for an AES byte substitution operation for preventing an information leakage attack, including: a first input field transformation unit receiving masked input data in GF(2⁸) and transformation selection data, creating a first transformation value through a specified transformation according to a value of the transformation selection data and outputting the first transformation value; a second input field transformation unit receiving a mask for the input data and the transformation selection data, creating a second transformation value for performing a mask correction of the first transformation value through a specified transformation and outputting the second transformation value; a masked inversion apparatus in GF((2⁴)²) calculating a masked inversion value by receiving and performing an inversion of an output mask, a plurality of random input masks and first and second transformation values; a first output field transformation unit receiving the inversion value and the transformation selection data and calculating a masked output value transformed in GF(2⁸) through a specified transformation; and a second output field transformation unit receiving the output mask and the transformation selection data and calculating a correction value for performing a mask correction of the output value through a specified transformation according to the value of the transformation selection data.

According to other aspects of the present invention, there are provided methods corresponding to the aforementioned apparatuses.

Additional and/or other aspects and advantages of the present invention will be set forth in part in the description which follows and, in part, will be obvious from the description, or may be learned by practice of the invention

### BRIEF DESCRIPTION OF THE DRAWINGS

FIG. 1 is a view illustrating structures of input data, state array having converted input data and encrypted or decrypted output data in a general AES rijndael algorithm;

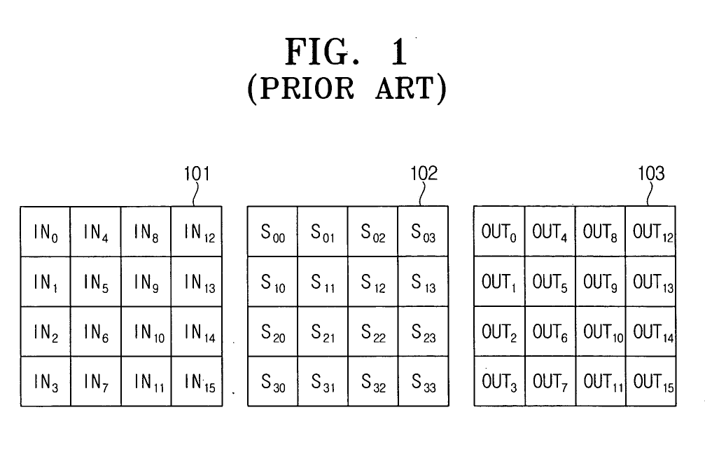

FIGS. 2A and 2B are flowcharts illustrating one round in a general rijndael algorithm;

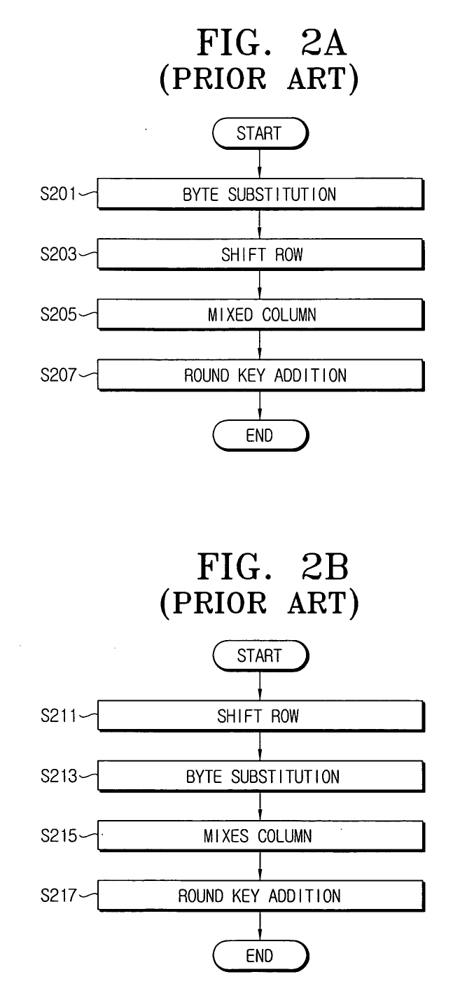

FIG. 3 is a block diagram illustrating the construction of a masked multiplication apparatus in GF(2ⁿ) according to a first embodiment of the present invention;

FIG. 4 is a flowchart explaining the operation of a masked multiplication apparatus in GF(2ⁿ) according to a first embodiment of the present invention;

FIG. 5 is a block diagram illustrating the construction of a masked inversion apparatus in GF((2⁴)²) according to a second embodiment of the present invention; and

FIG. 6 is a block diagram illustrating the construction of a masked AES byte substitution operation apparatus according to a third embodiment of the present invention.

### DETAILED DESCRIPTION OF EMBODIMENTS

Reference will now be made in detail to embodiments of the present invention, examples of which are illustrated in the accompanying drawings, wherein like reference numerals refer to the like elements throughout. The embodiments are described below in order to explain the present invention by referring to the figures.

Various embodiments of the present invention prevent an information leakage attack during a byte substitution operation. By randomly extracting input data using a data masking technology, the security of an AES computation can be improved. Since a watchman who accesses the leaked information cannot discriminate desired information from the randomly extracted data, the information leakage is minimized. A data masking technology includes a process of transforming data using a randomly extracted mask (hereinafter referred to as a “random mask”). The random mask is applied to the data through an exclusive OR (XOR) operation.

An AES encryption algorithm is implemented by a smart card for performing a data process with a secret key. In implementing the AES encryption algorithm, various embodiments of the present invention use a method of masking input data in order to prevent the information leakage. Since in an AES round algorithm, all operations except a byte substitution operation are linear, a mask correction for a masked data computation can be performed in a direct manner. The masked byte substitution operation requires mask data that is non-linearly processed.

In an embodiment of the present invention, a Galois field such as GF((2⁴)²) is used in order to reduce the complexity of the byte substitution operation in the synthesized GF. If this Galois field is used, the byte substitution operation is expressed as a plurality of combined multiplication in GF(2ⁿ), addition, square operation, constant multiplication and inversion operation. Many multiplications in GF(2⁴) secure an important part in the byte substitution operation.

A masked output value is calculated by receiving and performing a multiplication of two masked data in GF(2ⁿ), and thus actual input and output values are not exposed.

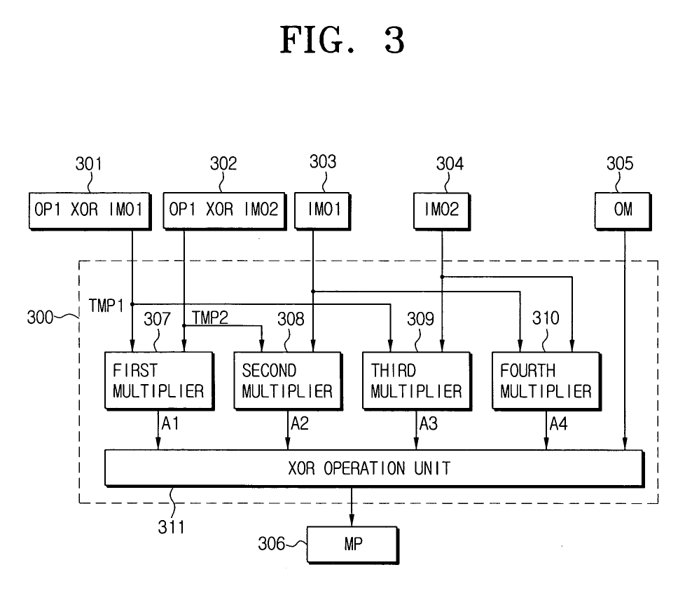

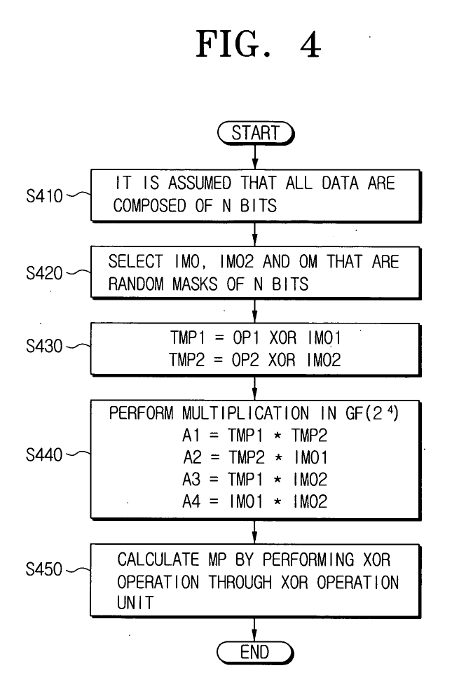

FIG. 3 is a block diagram illustrating the construction of a masked multiplication apparatus in GF(2ⁿ) according to a first embodiment of the present invention, and FIG. 4 is a flowchart explaining the operation of a masked multiplication apparatus in GF(2ⁿ) according to a first embodiment of the present invention. Referring to FIG. 3, a masked multiplication apparatus 300 in a Galois field includes respective first to fourth multipliers 307 to 310, and an XOR operation unit 311.

The respective first to fourth multipliers 307 to 310 receive and perform a multiplication of a plurality of data composed of n bits, and respective calculate n-bit intermediate values A1 to A4.

The XOR operation unit 311 receives the first to fourth intermediate values A1 to A4 from the respective first to fourth multipliers 307 to 310 and output masks (OM) 305 from the outside, and performs an XOR operation of the intermediate values and the output masks to calculate a final output value (MP) 306. Here, MP is a masked value.

Referring to FIGS. 3 and 4, it is assumed that all input data inputted to the masked multiplication apparatus 300 have a size of n bits (operation S410). Input data may be a first operand OP1, a second operand OP2, a first-operand mask (IMO1) 303, a second-operand mask (IMO2) 304, and the output mask (OM) 305.

Then, a first-operand random mask (IMO1) of n bits, a second-operand random mask (IMO2) and an output random mask (OM) are selected (operation S420).

Then, a masked value TMP1 is calculated by performing an XOR operation of the first random mask (IMO1) and the first operand OP1, and a masked value TMP2 is calculated by performing an XOR operation of the second random mask (IMO2) and the second operand OP2 (operation S430).

The masked TMP1 and TMP2 and the three masks (IMO1) 303, (IMO2) 304 and (OM) 305 are inputted to the respective multipliers as operands and used for calculation of the intermediate values A1 to A4 (operation S440).

The first intermediate value A1 is calculated by multiplying TMP1 and TMP2 on GF(2ⁿ). The second intermediate value A2 is calculated by multiplying TMP2 and IMO1 303 on GF(2ⁿ) in the same manner. The third intermediate value A3 is calculated by multiplying TMP1 and IMO2 304 on GF(2ⁿ), and the fourth intermediate value A4 is calculated by multiplying IMO1 303 and IMO2 304 on GF(2ⁿ).

The final output value (MP) 306 is calculated by performing an XOR operation of the OM, A4, A3, A2 and A1 through the XOR operation unit 311 (operation S450).

That is, MP=OM⊕A4⊕A3⊕A2⊕A1.

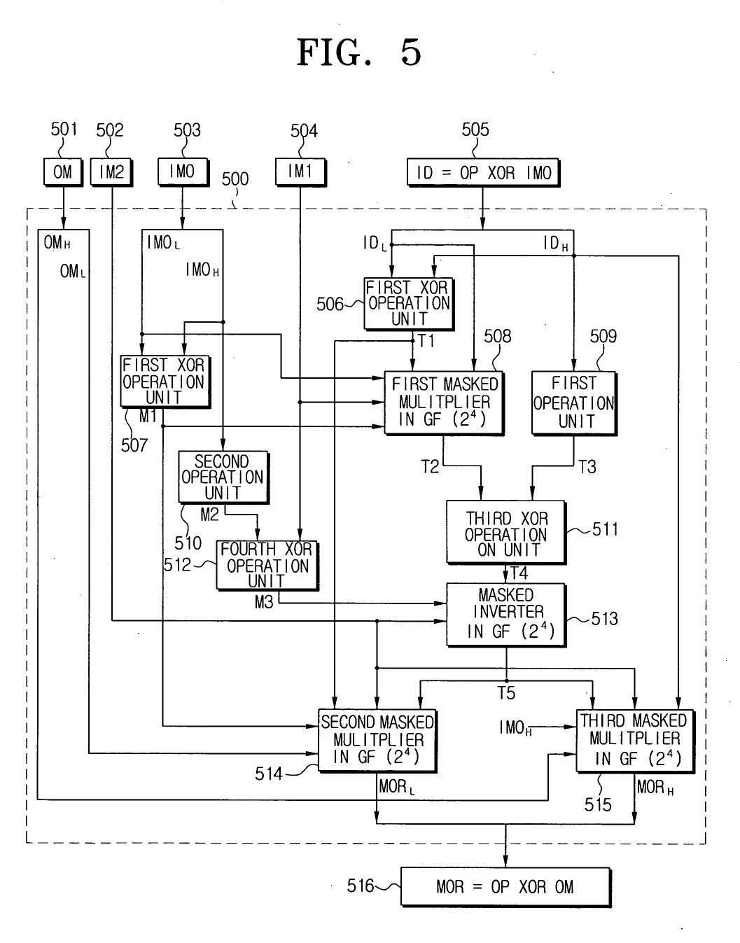

FIG. 5 is a block diagram illustrating the construction of a masked inversion apparatus in GF((2⁴)²) according to a second embodiment of the present invention.

The present embodiment performs a masked byte substitution in GF((2⁴)²) using a masked multiplication in GF(2ⁿ) (here, n=4). In order to perform the byte substitution operation in GF((2⁴)²), the present embodiment provides an apparatus for the masked inversion in GF((2⁴)²).

Referring to FIG. 5, the masked inversion apparatus 500 according to the present invention includes respective first to fourth XOR operation units 506, 507, 511 and 512, respective first to third masked multipliers 508, 514 and 515 in GF(2⁴), respective first and second operation units 509 and 510, and a masked inverter 513 in GF(2⁴).

The masked inversion apparatus 500 in GF((2⁴)²) receives an 8-bit output mask (OM) 501, a 4-bit random mask (IM2) 502, an 8-bit input operand mask (IMO) 503, a 4-bit random mask (IMI) 504 and an 8-bit masked operand (ID) 505 from an outside, and calculates an 8-bit output value (MOR) 516 through a specified operation process.

Here, the 8-bit masked operand (ID) 505 is expressed as follows:
ID=OP⊕IMO
wherein OP denotes an actual data value inversed in GF((2⁴)²).

The 8-bit output value (MOR) 516 is outputted as follows in a state that the actual inverted data value OP is not exposed.
MOR=OP⁻¹⊕OM

Each 8-bit input data 501, 503 and 505 is divided into two 4-bit data through a specified operation process. One of the divided data is constructed by extracting four lower bits of the 8-bit input data, which is indicated as an index L in FIG. 5. The other of the divided data is constructed by extracting four upper bits of the 8-bit input data, which is indicated as an index H in FIG. 5. For example, in FIG. 5, OMH is constructed by extracting the four upper bits from OM 501, and OML is constructed by extracting the four lower bits from OM 501.

The respective first to fourth XOR operation units 506, 507, 511 and 512 receive and perform an XOR operation of the 4-bit data and output 4-bit data.

The respective first to third masked multipliers 508, 514 and 515 in GF(2⁴) perform a masked multiplication in GF(2⁴).

The respective first to third masked multipliers 508, 514 and 515 in GF(2⁴) receive and perform a masked multiplication in GF(2⁴) of the first masked operand A, the second masked operand B, the first operand mask IMO1, the second operand mask IMO2 and the output mask (OM), and calculate masked output values including the output mask (OM) 501. Here, the first and second masked operands are as follows:
A=OPP1⊕IMO1;
B=OP2⊕IMO2.

Meanwhile, the respective first and second operation units 509 and 510 perform a square operation and a constant multiplication of the input data expressed by a polynomial in GF(2⁴). If the input data a(x) is a₀+a₁x+a₂x²+a₃x³ and the constant c(x) is 1+x³, the operation performed by the first and second operation units 509 and 510 is as follows:

$$\begin{matrix}{a ( x )}^{2} * c ( x ) = ( {a}_{0} + {a}_{1} x + {a}_{2} {x}^{2} + {a}_{3} {x}^{3} ) * ( {a}_{0} + {a}_{1} x + {a}_{2} {x}^{2} + {a}_{3} {x}^{3} ) * \\ 1 + {x}^{3} \\ = {a}_{0} + ( {a}_{1} + {a}_{3} ) x + {a}_{3} {x}^{2} + ( {a}_{0} + {a}_{2} ) {x}^{3}\end{matrix}$$

Here, an irreducible polynomial f(x)=1+x+x⁴ is used for the multiplication.

Output values of the first and second operation units 509 and 510 are used only as the operands of the XOR operation by the third and fourth XOR operation units 511 and 512.

The masked inverter 513 in GF(2⁴) performs a masked inversion of the 4-bit masked input data. That is, the masked inverter 513 in GF(2⁴) receives a masked operand C as its first input, an operand mask as its second input and an output mask as its third input, and calculates a masked output value. Here, the masked operand is OP XOR MIN. If the input is C and the result of inversion is D, the masked operand becomes D=C⁻¹ mod f(x). Since the computation of D is performed using a table search technology that is a general mask inversion technology or a masking AND operation in an inversion synthesizing process, the actual C value is not disposed.

The first XOR operation unit 506 receives and performs an XOR operation of an upper bit part ID_{H} and a lower bit part ID_{L} of the data ID 505 inputted to the masked inversion apparatus 500 in GF((2⁴)²), and outputs the resultant value of the XOR operation to the first and second masked multipliers 508 and 514 in GF(2⁴).

The first masked multiplier 508 in GF(2⁴) receives and performs a multiplication of the output value of the first XOR operation unit 506, the lower bit part IMO2 of IMO 503, the output value of the second XOR operation unit 507, the lower bit part ID_{L} of ID 505 and IM1 504, and outputs the result of multiplication to the third XOR operation unit 511.

The first operation unit 509 receives and performs a square operation and a constant multiplication of the upper bit part IDH of ID 505, and outputs the result of the square operation and constant multiplication to the third XOR operation unit 511.

The third XOR operation unit 511 receives and performs an XOR operation of the output value of the first masked multiplier 508 in GF(2⁴) and the output value of the first operation unit 509, and outputs the result of the XOR operation to the masked inverter 513 in GF(2⁴).

The second operation unit 510 receives and performs a square operation and a constant multiplication of the upper bit part IMOH of IMO 503, and outputs the result of the square operation and constant multiplication to the fourth XOR operation unit 512.

The fourth XOR operation unit 512 receives and performs an XOR operation of the output of the second operation unit 510 and IM1 504, and outputs the result of the XOR operation to the masked inverter 513 in GF(2⁴).

The masked inverter 513 in GF(2⁴) receives and performs a specified operation of the output value of the fourth XOR operation unit 512, the output value of the third XOR operation unit 511 and IM2 502, and outputs the result of the operation to the second masked multiplier 514 in GF(2⁴) and the third masked multiplier 515.

The second masked multiplier 514 in GF(2⁴) receives and performs a specified operation of the output value of the first XOR operation unit 506, the output value of the second XOR operation unit 507, the output value of the masked inverter 513 in GF(2⁴), the lower bit part OM_{L} of OM 501 and IM2 502, and outputs a data value corresponding to the lower bit part MOR_{L} of the final output value (MOR) 516.

The third masked multiplier 515 in GF(2⁴) receives and performs a specified operation of the output value of the masked inverter 513 in GF(2⁴), the upper bit part ID_{H} of ID 505, IM2 502, the upper bit part IMO_{L} of IM2 502 and the upper bit part OMH of OM 501, and outputs a data value corresponding to the upper bit part MOR_{H} of the final output value (MOR) 516.

Hereinafter, the operation of the masked inversion apparatus 500 in GF((2⁴)²) will be explained. The respective second and fourth XOR operation units 507 and 512 and the second operation unit 510 take charge of the mask correction in the masked inversion apparatus 500, and the remaining parts take charge of the masked data processing.

In the event that the input value is a and the resultant value of inversion is b, the inversion process in GF((2⁴)²) where the data is not masked will now be explained.

First, the input value a is divided into an upper 4-bit part a_{H} and a lower 4-bit part a_{L}, and all operations including multiplication, inversion, etc., in GF((2⁴)²) are performed. The operation processes performed in order are as follows:
(a) T1=a_{L}⊕a_{H};
(b) T=T1*a_{L}=(a_{L}⊕a_{H})*a_{L};
(c) T3=a_{H}²*(1001);
(d) T4=T2⊕T3=(a_{L}⊕a_{H})*a_{L}⊕a_{H}²*(1001);
(e) T5=T4⁻¹=[(a_{L}⊕a_{H})*a_{L}⊕a_{H}²((1001)]⁻¹;
(f) b_{L=T5*T1=(a}_{L}⊕a_{H})*(a_{L}⊕a_{H}²)*(1001)]⁻¹; and
(g) b_{H}=T5*a_{H}=a_{H}*([(a_{L}⊕a_{H})*a_{L}⊕a_{H}²*(1001)]⁻¹.

Using b_{H} and b_{L} calculated through the above processes, the output b in GF((2⁴)²) is obtained: b=a⁻¹ in GF((2⁴)²).

Hereinafter, the masked inversion process according to the present embodiment will be explained with reference to FIG. 5.

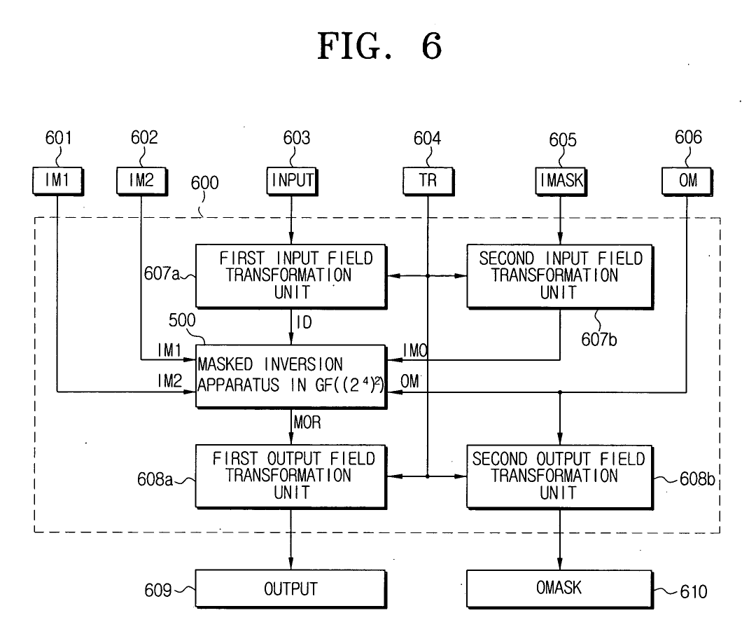

In the process below, Tᵢ is masked variable and Mᵢ is a mask used for Tᵢ.
1. Random masks are selected: 8-bit IMO 503, 4-bit IM1 504, 4-bit IM2 402 and 8-bit output mask (OM) 501
2. ID 505 is calculated:
   ID=OP⊕IMO.
   ID 505 inputted to the masked inversion apparatus 500 in GF((2⁴)²) is divided into an upper 4-bit part ID_{H} and a lower 4-bit part ID_{L}.
3. All operations including multiplication and inversion in GF((2⁴)²) are performed.
(a) The first XOR operation unit 506 performs the following operation:
   T1=(OP_{L}⊕OP_{H})⊕(IMO_{L}⊕IMO_{H}).
   At the same time, the second XOR operation unit 507 performs the following operation in order to calculate the correction value M1 for the mask correction of T1:
(b) The first masked multiplier 508 in GF(2⁴) performs the following operation using IM1 504, the lower 4-bit part IMO_{L} of IMO 503 and the output value M1 of the second XOR operation unit 507. Here, the mask correction is not required, and IM1 is used as a new mask:
   T2=T1*OP_{L}=(OP_{L}⊕OP_{H})*OP_{L}⊕IM1.
(c) The first operation unit 509 performs the following operation:
   T3=OP_{H}²*(1001)⊕IMO_{H}²*(1001).
   At the same time, the second operation unit 510 performs a mask correction of the output value T3 of the first operation unit 509 and calculates the correction value M2 as follows:
   M2=IMO_{H}²*(1001)
(d) Then, the third XOR operation unit 511 performs the following operation:
   T4=(OP_{L}⊕OP_{H})*OP_{L}⊕OP_{H}²*(1001)⊕IM1⊕IMO_{H}²*(1001).
   Then, the fourth XOR operation unit 512 performs a mask correction of the output value T4 of the third XOR operation unit 511 and calculates the correction value M3 as follows:
   M3=IM1⊕IMO_{H}²*(1001).
(e) The masked inverter 513 in GF(2⁴) performs a masked inversion operation using the output value M3 of the fourth XOR operation unit 512 and IM2 502. Here, the msk correction is not required, and IM2 502 is used as a new mask:
   T5=[(OP_{L}⊕OP_{H})*OP_{L}⊕OP_{H}²*(1001)]⁻¹
   (f) The second masked multiplier 514 in GF(2⁴) performs the following operation using the lower 4-bit part OM_{L} of OM 501, IM2 502, the output value M1 of the second XOR operation unit 510, etc., and calculates the lower 4-bit part MOR_{L} of the final output value MOR 516. Here, the mask correction is not required:
   MOR_{L}=T5*T1=(OP_{L}⊕OP_{H})*[(OP_{L}⊕OP_{H})*OP_{L}⊕OP_{H}²*(1001)]⁻¹.
(g) The third masked multiplier 515 in GF(2⁴) performs the following operation using the upper 4-bit part OM_{H} of OM 501, IM2 502, the upper 4-bit part IMO_{H} of IMO 503, etc., and calculates the upper 4-bit part MOR_{H} of the final output value MOR 516. Here, the mask correction is not required:
   MOR_{H}=T5*OP_{H}=OP_{H}*[(OP_{L}⊕OP_{H})*OP_{L}⊕OP_{H}²*(1001)]⁻¹.
4. The final output value MOR 516 is calculated from MOR_{H} and MOR_{L} as calculated above. Here, OM 701 is the output mask:
   MOR=OP⁻¹⊕OM.
   FIG. 6 is a block diagram illustrating the construction of a masked AES byte substitution operation apparatus according to a third embodiment of the present invention.

Referring to FIG. 6, the masked inversion apparatus 500 in GF((2⁴)²) is the same as the masked inversion apparatus in GF((2⁴)²) as illustrated in FIG. 5, and the explanation thereof will be made with reference to the same reference numerals.

The masked AES byte substitution operation apparatus 600 according to the present embodiment includes a first input field transformation unit 607a, a second input field transformation unit 607b, the masked inversion apparatus 500 in GF((2⁴)²), a first output field transformation unit 608a and a second output field transformation unit 608b.

The masked AES byte substitution operation apparatus 600 according to the present embodiment receives and performs a specified operation of a random mask (IM1) 601, a random mask (IM2) 602, a masked data INPUT) 603, a transformation selection data (TR) 604, an input data mask (IMASK) 605 and an output mask (OM) 606, and outputs a first output value (OUTPUT) 609 and a second output value (OMASK) 610. Here, OMASK 610 is the mask correction value.

The masked AES byte substitution operation apparatus 600 according to the present embodiment performs a substitution operation of masked bytes of the AES rijndael algorithm using additional random masks. The apparatus outputs a masked resultant value having an output mask that does not expose an actual value of the input data.

The first input field transformation unit 607a receives and performs a transformation of masked data (INPUT) 603 and transformation selection data (TR) 604 according to a specified condition and provides its output value to the masked inversion apparatus 500 in GF((2⁴)²).

The second input field transformation unit 607b receives and performs a transformation of input data mask (IMASK) 605 and the transformation selection data (TR) 604 according to a specified condition and provides its output value to the masked inversion apparatus 500 in GF((2⁴)²).

The masked inversion apparatus 500 in GF((2⁴)²) receives and performs an inversion of OM 606, IM1 601, an output value of the second input field transformation unit, IM2 602 and an output value of the first input field transformation unit and provides its output value to the first output field transformation unit 608a.

The first output field transformation unit 608a receives the output value of the masked inversion apparatus 500 in GF((2⁴)²) and the transformation selection data (TR) 604 and calculates the first output value (OUTPUT) 609.

The second output field transformation unit 608b receives OM 606 and the transformation selection data (TR) 604, performs a transformation according to a specified condition, and calculates the second output value (OMASK) 610.

First, the first input field transformation unit 607a, which has received the masked data 603 in GF(2⁸), outputs the masked data transformed in GF((2⁴)²) according to the value of the transformation selection data 604 that is another input, or performs a transformation of the masked data 603 according to an inverse affine transformation of rijndael on GF(2⁸) and then outputs the masked data transformed in GF((2⁴)²).

The second input field transformation unit 607b processes the input data mask (IMASK) 605 according to the transformation selection data (TR) 604, performs the mask correction of the data outputted from the first input field transformation unit 608a, and outputs the correction value IMO to the masked inversion apparatus 500 in GF((2⁴)²).

The masked inversion apparatus 500 in GF((2⁴)²) performs an inversion of the data using the output value of the first input field transformation unit, the random mask (IM1) 601 and IM2 602, performs a transform of the input mask IMO into GF((2⁴)²), and outputs the resultant masked value MOR of inversion together with the mask OM.

The first output field transformation unit 608a receives the masked data MOR in GF((2⁴)²) from the masked inversion apparatus 500 and performs a transform of the masked data into GF(2⁸) according to the value of the transformation selection data (TR) 604 that is the second input. Then, the first output field transformation unit 608a performs a rijndael inverse affine transformation of the data or outputs the masked data transformed into GF(2⁸).

The second output field transformation unit 608b processes the output mask (OM) 606 according to the value of the transformation selection data (TR) 804, and calculates the correction value (OMASK) 610 by performing a mask correction of the data outputted from the first output field transformation unit 608.

The transformations between GF(2⁸) and GF((2⁴)²) are a field isomorphic transformation and an inverse field isomorphic transformation. The field isomorphic and inverse isomorphic transformations are defined as follows:
GF(2⁸)→GF((2⁴)²):x→y=T_{□}x; [Equation 1]
and
GF((2⁴)²)→GF(2⁸):y→x=T⁻¹_{□}y.
Here, x denotes an element of a Galois field GF(2⁸), and y denotes an element of the Galois field GF((2⁴)²).

Also, T is a field isomorphic transformation matrix, and T⁻¹ is an inverse field isomorphic transformation matrix:

$$T = [ \begin{matrix}1 & 0 & 1 & 1 & 1 & 0 & 1 & 1 \\ 0 & 1 & 0 & 1 & 0 & 0 & 0 & 0 \\ 0 & 1 & 0 & 0 & 1 & 0 & 1 & 0 \\ 0 & 1 & 1 & 0 & 0 & 0 & 1 & 1 \\ 0 & 0 & 0 & 0 & 1 & 1 & 1 & 0 \\ 0 & 1 & 0 & 0 & 1 & 0 & 1 & 1 \\ 0 & 0 & 1 & 1 & 0 & 1 & 0 & 1 \\ 0 & 0 & 0 & 0 & 0 & 1 & 0 & 1\end{matrix} ]$$

$${T}^{- 1} = [ \begin{matrix}1 & 0 & 0 & 0 & 1 & 0 & 1 & 0 \\ 0 & 0 & 0 & 0 & 1 & 1 & 0 & 1 \\ 0 & 1 & 0 & 0 & 1 & 1 & 1 & 0 \\ 0 & 1 & 0 & 0 & 1 & 1 & 0 & 1 \\ 0 & 1 & 0 & 1 & 1 & 0 & 1 & 0 \\ 0 & 0 & 1 & 0 & 0 & 1 & 0 & 1 \\ 0 & 1 & 1 & 1 & 0 & 1 & 1 & 1 \\ 0 & 0 & 1 & 0 & 0 & 1 & 0 & 0\end{matrix} ]$$

The transformation of Equation 1 is performed through performing of a matrix multiplication of respective matrices with respect to the input data.

The inverse affine transformation and the operation of the inverse field isomorphism are defined as follows:

$$\begin{matrix}z = {A}^{′} • y + {c}^{′} , {A}^{′} = T • {A}^{- 1} , {c}^{′} = {A}^{′} • c \\ {A}^{′} = T \cdot {A}^{- 1} = [ \begin{matrix}0 & 1 & 0 & 0 & 0 & 1 & 0 & 0 \\ 0 & 0 & 1 & 1 & 0 & 1 & 1 & 0 \\ 0 & 1 & 0 & 1 & 0 & 1 & 0 & 0 \\ 0 & 0 & 0 & 0 & 0 & 1 & 0 & 1 \\ 1 & 1 & 1 & 0 & 1 & 1 & 1 & 1 \\ 0 & 0 & 0 & 1 & 1 & 1 & 1 & 0 \\ 1 & 0 & 0 & 0 & 1 & 1 & 1 & 0 \\ 0 & 1 & 1 & 0 & 0 & 0 & 1 & 1\end{matrix} ] , \\ {C}^{′} = {A}^{′} \cdot C = [ \begin{matrix}0 \\ 0 \\ 0 \\ 1 \\ 0 \\ 0 \\ 1 \\ 0\end{matrix} ]\end{matrix} \qquad [ Equation 2 ]$$

The transformation of Equation 2 is performed through performing of a matrix multiplication and a matrix addition of respective matrices with respect to the input data.

The inverse field isomorphic transformation and the affine transformation are defined by Equation 3 below:
y=A′⁻1□z+c, A′⁻¹=A□T⁻¹ [Equation 3]
Here, A′⁻¹ is as follows:

$${A}^{′ - 1} = A \cdot {T}^{- 1} = [ \begin{matrix}1 & 0 & 1 & 0 & 0 & 1 & 1 & 0 \\ 1 & 1 & 1 & 1 & 0 & 0 & 0 & 1 \\ 1 & 0 & 0 & 1 & 1 & 0 & 1 & 0 \\ 1 & 0 & 1 & 0 & 0 & 0 & 0 & 0 \\ 1 & 1 & 0 & 1 & 1 & 1 & 1 & 0 \\ 0 & 1 & 1 & 1 & 0 & 0 & 0 & 1 \\ 0 & 0 & 0 & 0 & 1 & 0 & 1 & 1 \\ 0 & 1 & 1 & 0 & 0 & 0 & 0 & 1\end{matrix} ] , c = [ \begin{matrix}1 \\ 1 \\ 0 \\ 0 \\ 0 \\ 1 \\ 1 \\ 0\end{matrix} ]$$

The transformation of Equation 3 is performed through a matrix multiplication and a matrix addition of respective matrices with respect to the input data.

Equations related to the field isomorphic transformation, the inverse affine transformation and the inverse field isomorphic transformation are as follows:
y₀=x₀⊕x₂⊕x₃⊕x₄⊕x₆⊕x₇
z₀=x₁⊕x₅
y=x₁⊕x₃
z₁=x₂⊕x₃⊕x₅⊕x₆
y₂=x₁⊕x₄⊕x₆
z₂=x₁⊕x₃⊕x₅
y₃=x₁⊕x₂⊕x₆⊕x₇
\overline{z₃}x₅⊕x₇
y₄=x₄⊕x₅⊕x₆
z₄=x₀⊕x₁⊕x₂⊕x₄⊕x₅⊕x₆⊕x₇
y₅=x₁⊕x₄⊕x₆⊕x₇
z₅=x₃⊕x₄⊕x₅⊕x₆
y₆=x₂⊕x₃⊕x₅⊕x₇
\overline{z₆}x₀⊕x₄⊕x₅⊕x₆
y₇=x₅⊕x₇
z₇=x₁⊕x₂⊕x₆⊕x₇
Here, a⊕b is a bit-type XOR operation between a and b.

Equations related to the inverse field isomorphic transformation, the inverse affine transformation and the inverse field isomorphic transformation are as follows:
z₀=x₀⊕x₄⊕x₆
\overline{y₀}x₀⊕x₂⊕x₅⊕x₆
z₁=x₄⊕x₅⊕x₇
\overline{y₁}=x₀⊕x₁⊕x₂⊕x₃⊕x₇
z₂=x₁⊕x₄⊕x₅⊕x₆
y₂=x₀⊕x₃⊕x₄⊕x₆
z₃=x₁⊕x₄⊕x₅⊕x₇
y₃=x₀⊕x₂
z₄=x_{1⊕x}₃⊕x₄⊕x₆
y₄=x₀⊕x₁⊕x₃⊕x₄⊕x₅⊕x₆
z₅=x₂⊕x₅⊕x₇
\overline{y₅}x₁⊕x₂⊕x₃⊕x₇
z₆=x₁⊕x₂⊕x₃⊕x₄⊕x₅⊕x₆⊕x₇
\overline{y₆}=x₄⊕x₆⊕x₇
z₇=x₂⊕x₅
y₇=x₁⊕x₂⊕x₇

Accordingly, the respective first and second input field transformation units 607a and 607b and the first and second output field transformation units 608a and 608b perform the transformation using the XOR operation and NOT operation.

In order to perform the byte substitution operation, the transformation selection data (TR) signal is set to 0. Then, the first input field transformation unit 607a performs the transformation of the masked data transformed into GF((2⁴)²) and the mask. Then, the masked inversion apparatus 500 in GF((2⁴)²) performs the masked inversion in GF((2⁴)²) and applies the mask to the output value. Finally, the first output field transformation unit 608a transforms the masked data MOR and the mask OM into GF(2⁸), and then outputs the first output value (OUTPUT) 609 by performing the rijndael affine transformation. The first output value (OUTPUT) 609 includes a resultant value of performing the byte substitution operation, and the second output value (OMASK) 610 includes the mask for the masked data.

In order to perform the inverse byte substitution operation, the transformation selection data (TR) signal is set to 1. Then, the first and second input field transformation units 607a and 607b perform the rijndael inverse affine transformation of the masked data and the mask in GF(2⁸), and then perform the inversion into GF((2⁴)²). Then, the masked inversion apparatus 500 in GF((2⁴)²) performs the masked inversion in GF((2⁴)²) and applies the resultant value to the mask (OM) 606. Finally, the first and second output transformation units transform the inversion of the data MOR masked in GF(2⁸) and the mask (OM) 606 in GF(2⁸). The first output value (OUTPUT) 609 includes a resultant value of performing the inverse byte substitution operation with respect to the masked data, and the second output value (OMASK) 610 includes the mask for the masked data.

According to the AES byte substitution operation of the above-described embodiments of the present invention, the masked computation is performed so that the actual data is not disposed, and thus the information leakage attack can be prevented.

According to the above-described embodiments of the present invention, the complexity of the masked multiplication can be reduced, and the information leakage can be prevented since the input data and the resultant output are masked data. Also, according to the present invention, the scale of hardware required for the AES byte substitution operation can be reduced so as to be suitable for the resource-qualified environment such as a smart card.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A method of multiplication in a Galois field (GF) for preventing an information leakage attack by performing a transformation of masked data and masks in GF(2ⁿ), the method comprising:
receiving a plurality of first and second masked input data, a plurality of first and second input masks and an output mask;
calculating a plurality of intermediate values by performing a multiplication of the plurality of masked input data and the plurality of input masks in GF(2ⁿ); and
calculating a final masked output value by performing an XOR operation of the intermediate values and the output masks.

2. The method as claimed in claim 1, wherein the first input data refers to a value obtained by performing an exclusive OR (XOR) operation of a first input operand and the first input mask, and the second input data refers to a value obtained by performing an XOR operation of a second input operand and the second input mask.

3. The method as claimed in claim 1, calculating includes:
calculating a first intermediate value by performing an XOR operation of the first input data and the second input data;
calculating a second intermediate value by performing an XOR operation of the second input data and the first input mask;
calculating a third intermediate value by performing an XOR operation of the first input data and the second input mask; and
calculating a fourth intermediate value by performing an XOR operation of the first input mask and the second input mask.

4. The method as claimed in claim 1, wherein the final output value (MP) is calculated by a following equation
MP=OM⊕A4⊕A3⊕A2⊕A1,
and
wherein ⊕ denotes the XOR operation, OM the output mask, A1 the first intermediate value, A2 the second intermediate value, A3 the third intermediate value and A4 the fourth intermediate value.

5. An apparatus for multiplication in a Galois field (GF) for preventing an information leakage attack by performing a transformation of masked data and masks in GF(2ⁿ), the apparatus comprising:
a plurality of multipliers receiving a plurality of first and second masked input data, a plurality of first and second input masks and an output mask, and calculating intermediate values by performing a multiplication of the plurality of masked input data and the plurality of input masks in GF(2ⁿ); and
an exclusive OR (XOR) operation unit calculating a final masked output value by performing an XOR operation of the intermediate values and the output masks.

6. The apparatus as claimed in claim 5, wherein the first input data refers to a value obtained by performing an XOR operation of a first input operand and the first input mask, and the second input data refers to a value obtained by performing an XOR operation of a second input operand and the second input mask.

7. The apparatus as claimed in claim 5, wherein the plurality of multipliers includes:
a first multiplier calculating a first intermediate value by performing an XOR operation of the first input data and the second input data;
a second multiplier calculating a second intermediate value by performing an XOR operation of the second input data and the first input mask;
a third multiplier calculating a third intermediate value by performing an XOR operation of the first input data and the second input mask; and
a fourth multiplier calculating a fourth intermediate value by performing an XOR operation of the first input mask and the second input mask.

8. The apparatus as claimed in claim 5, wherein the final output value (MP) is calculated by a following equation
MP=OM⊕A4⊕A3⊕A2⊕A1,
and
wherein ⊕ denotes the XOR operation, OM the output mask, A1 the first intermediate value, A2 the second intermediate value, A3 the third intermediate value and A4 the fourth intermediate value.

9. An apparatus for inversion in a Galois field (GF) for receiving first to fifth input data from an outside and performing and inversion of the input data in GF((2⁴)²), the apparatus comprising:
a first exclusive OR (XOR) operation unit calculating a first resultant value T1 by receiving and performing an XOR operation on an upper bit part and a lower bit part of the fifth input data composed of 8 bits;
a second exclusive OR (XOR) operation unit calculating a first correction value M1 for performing a mask correction of the first resultant value T1 by receiving and performing an XOR operation on an upper bit part and a lower bit part of the third input data composed of 8 bits;
a first masked multiplier calculating a second operation value T2 by receiving and performing a multiplication on the first resultant value T1, the lower bit part of the fifth input data, the first correction value M1, the lower bit part of the third input data and the fourth input data in GF(2⁴);
a first operation unit calculating a third operation value T3 by receiving and performing a specified operation on the upper bit part of the fifth input data;
a second operation unit calculating a second correction value M2 for correcting the third operation value T3 by receiving and performing a specified operation on the upper bit part of the third input data;
a third XOR operation unit calculating a fourth operation value T4 by receiving and performing an XOR operation on the third operation value T3 and the second operation value T2;
a fourth XOR operation unit calculating a third correction value M3 for performing a mask correction on the fourth operation value T4 by receiving and performing an XOR operation on the second correction value M2 and the fourth input data;
a masked inverter calculating a fifth operation value (T5) by receiving and performing an inversion operation on the fourth operation value T4, the third correction value M3 and a lower bit part of the first input data in GF(2⁴);
a second masked multiplier calculating a lower bit part of a final output value by receiving and performing a multiplication on the fifth operation value, the first operation value, the second input data, the first correction value and the lower bit part of the first input data in GF(2⁴); and
a third masked multiplier calculating an upper bit part of the final output value by receiving and performing a multiplication on the fifth operation value, the lower bit part of the fifth input data, the second input data, the upper bit part of the third input data and an upper bit part of the first input data in GF(2⁴).

10. An apparatus for an advanced encryption standard (AES) byte substitution operation for preventing an information leakage attack, the apparatus comprising:
a first input field transformation unit receiving masked input data in GF(2⁸) and transformation selection data, creating a first transformation value through a specified transformation according to a value of the transformation selection data and outputting the first transformation value;
a second input field transformation unit receiving a mask for the input data and the transformation selection data, creating a second transformation value for performing a mask correction of the first transformation value through a specified transformation and outputting the second transformation value;
a masked inversion apparatus in GF((2⁴)²) calculating a masked inversion value by receiving and performing an inversion of an output mask, a plurality of random input masks and first and second transformation values;
a first output field transformation unit receiving the inversion value and the transformation selection data and calculating a masked output value transformed in GF(2⁸) through a specified transformation; and
a second output field transformation unit receiving the output mask and the transformation selection data and calculating a correction value for performing a mask correction of the output value through a specified transformation according to the value of the transformation selection data.

11. A method of inversion in a Galois field (GF) for receiving first to fifth input data and performing and inversion of the input data in GF((2⁴)²), the method comprising:
calculating a first resultant value T1 by receiving and performing an exclusive OR (XOR) operation on an upper bit part and a lower bit part of the fifth input data composed of 8 bits;
calculating a first correction value M1 for performing a mask correction of the first resultant value T1 by receiving and performing an exclusive OR (XOR) operation on an upper bit part and a lower bit part of the third input data composed of 8 bits;
calculating a second operation value T2 by receiving and performing a multiplication on the first resultant value T1, the lower bit part of the fifth input data, the first correction value M1, the lower bit part of the third input data and the fourth input data in GF(2⁴);
calculating a third operation value T3 by receiving and performing a specified operation on the upper bit part of the fifth input data;
calculating a second correction value M2 for correcting the third operation value T3 by receiving and performing a specified operation on the upper bit part of the third input data;
calculating a fourth operation value T4 by receiving and performing an exclusive OR (XOR) operation on the third operation value T3 and the second operation value T2;
calculating a third correction value M3 for performing a mask correction on the fourth operation value T4 by receiving and performing an exclusive OR (XOR) operation on the second correction value M2 and the fourth input data;
calculating a fifth operation value (T5) by receiving and performing an inversion operation on the fourth operation value T4, the third correction value M3 and a lower bit part of the first input data in GF(2⁴);
calculating a lower bit part of a final output value by receiving and performing a multiplication on the fifth operation value, the first operation value, the second input data, the first correction value and the lower bit part of the first input data in GF(2⁴); and
calculating an upper bit part of the final output value by receiving and performing a multiplication on the fifth operation value, the lower bit part of the fifth input data, the second input data, the upper bit part of the third input data and an upper bit part of the first input data in GF(2⁴).

12. A method of advanced encryption standard (AES) byte substitution for preventing an information leakage attack, the method comprising:
receiving masked input data in GF(2⁸) and transformation selection data, creating a first transformation value through a specified transformation according to a value of the transformation selection data and outputting the first transformation value;
receiving a mask for the input data and the transformation selection data, creating a second transformation value for performing a mask correction of the first transformation value through a specified transformation and outputting the second transformation value;
calculating a masked inversion value by receiving and performing an inversion of an output mask, a plurality of random input masks and first and second transformation values;
receiving the inversion value and the transformation selection data and calculating a masked output value transformed in GF(2⁸) through a specified transformation; and
receiving the output mask and the transformation selection data and calculating a correction value for performing a mask correction of the output value through a specified transformation according to the value of the transformation selection data.
